(19) United States
(12) Patent Application Publication
(10) Pub. No.: US 2006/0185588 A1
(43) Pub. Date: Aug. 24, 2006

(54) Vapor deposition apparatus measuring film thickness by irradiating light

(75) Inventors: Toshihisa Nozawa, Amagasaki-Shi (JP); Masaji Inoue, Nishinomiya-Shi (JP)

Correspondence Address: CROWELL & MORING LLP;INTELLECTUAL PROPERTY GROUP, P.O. BOX 14300, WASHINGTON, DC, 20044-4300, US

(73) Assignee: Tokyo Electron Limited, Minato-Ku (JP)

(21) Appl. No.: 11/314,244

(22) Filed: Dec. 22, 2005

(30) Foreign Application Priority Data
Dec. 22, 2004 (JP) 2004-371407

(51) Int. Cl. B05C 11/00; C23C 16/00

(52) U.S. Cl. 118/712; 118/726; 118/715

(57) ABSTRACT

A substrate to be processes is accommodated in a process container. A vapor deposition source retains a vapor deposition material to be deposited on the substrate to be processed. A measuring device measures a film thickness of a vapor deposition film produced in said process container. The measuring device measures the film thickness by irradiating a light onto the vapor deposition film.

### BACKGROUND OF THE INVENTION

1. Field of the Invention

The present invention relates to vapor deposition apparatuses and, more particularly, to a vapor deposition apparatus having a film thickness measuring mechanism.

2. Description of the Related Art

Conventionally, as a method of forming a thin film on a surface of a substrate to be processed, a vapor deposition method is known. The vapor deposition method is a method for forming a thin film on a substrate to be processed by vapor-depositing a raw material, which has been vaporized or sublimated, on the object to be processed.

For example, as a thin film formed by the vapor deposition method, there is a thin film used for an organic electroluminescence (hereinafter, referred to as EL) element. The display device using the organic EL element has a small size and low power consumption, and is capable of performing surface luminescence. Additionally, it can reduce an apply voltage greatly as compared to a liquid crystal display. For these reasons, it is used for various display apparatus such as a flat display or the like.

The organic EL element has, for example, a structure in which a luminescence layer is formed between an anode and a cathode. The luminescence layer is a layer which emits a light by recombination of electrons and holes. Materials such as polycyclic aromatic hydrocarbon, hetero aromatic compound, organic metal complex compound, etc., are used for the luminescence layer. A thin film of such a material can be formed by the vapor deposition method. Additionally, a thin film for improving luminescence efficiency, such as, for example, a hole transportation layer or an electron transportation layer, may be formed between an anode and the luminescence layer or between a cathode and the luminescence layer, if it is needed. These layers can also be formed by the vapor deposition method.

The vapor deposition apparatus used for forming the above-mentioned thin film is equipped with a process container of which interior can be maintained at a depressurized state and a vapor deposition source, which is located inside the process container to vaporize or sublimate a vapor deposition raw material. The vapor deposition raw material vaporized and sublimated by the vapor deposition source is deposited on a substrate to be processed.

The vapor deposition apparatus of the above-mentioned structure is disclosed in Japanese Laid-Open Patent Application No. 2000-282219.

Here, when forming a thin film using the vapor deposition apparatus, there is a problem in that it is difficult to control an amount of the vapor deposition raw material vaporized or sublimated in the vapor deposition source.

That is, an amount of the raw material vaporized or sublimated per unit time in the vapor deposition source varies with a change in various vapor deposition conditions, and it is difficult to grasp accurately how much amount of the vapor deposition raw material has been actually vaporized or sublimated from the vapor deposition source. As a cause of the variation of an amount of the raw material vaporized or sublimated, there is a change in an amount of the vapor deposition raw material retained in the vapor deposition source, a slight change in a temperature of the vapor deposition source, or the like. It is difficult to sense changes in conditions of vapor deposition, which are causes of those, and, therefore, it is difficult to stabilize a film deposition rate of a vapor deposition film. Additionally, when forming a vapor deposition film on a plurality of substrate to the processed, there is a problem in that the film deposition rate varies, which causes a variation in a film thickness.

### SUMMARY OF THE INVENTION

It is a general object of the present invention to provide an novel and useful vapor deposition apparatus in which the above-mentioned problems are eliminated.

A more specific object of the present invention is to provide a vapor deposition apparatus which can control a thickness of a film formed by vapor deposition with good accuracy.

In order to achieve the above-mentioned objects, there is provided according to the present invention a vapor deposition apparatus comprising: a process container in which a substrate to be processed is accommodated; a vapor deposition source that retains a vapor deposition material to be deposited on the substrate to be processed; and a measuring device that measures a film thickness of a vapor deposition film produced in said process container, wherein said measuring device measures the film thickness by irradiating a light onto said vapor deposition film.

According to the present invention, a vapor deposition apparatus gives a good controllability of a film thickness of the vapor deposition film formed when forming the vapor deposition film.

In the vapor deposition apparatus according to the present invention, it is preferable that the light is a laser light. Additionally, it is preferable that the light is irradiated onto the vapor deposition film produced in a vicinity of said substrate to be processed in the process container.

In the vapor deposition apparatus according to the present invention, it is preferable that the measuring device is an ellipsometer. Additionally, the measuring device may comprises: a light-irradiating part that irradiates the light onto the vapor deposition film; and a light-measuring part that measures a luminescence intensity of luminescence of the vapor deposition film according to irradiation of the light. Further, the vapor deposition apparatus according to the present invention may comprise a spectrometry part that performs spectrometry on the luminescence of the vapor deposition film.

Additionally, the vapor deposition apparatus according to the present invention may comprise a control part that controls the vapor deposition source in accordance with the luminescence intensity. The control part may control a heater provided in said vapor deposition source.

Additionally, in the vapor deposition apparatus according to the present invention, it is preferable that the measuring device is provided outside the process container.

Additionally, in the vapor deposition apparatus according to the present invention, the process container may have a light-transmitting part that causes the light to transmit therethrough.

Other objects, features and advantages of the present invention will become more apparent from the following detailed description when read in conjunction with the accompanying drawings.

### BRIEF DESCRIPTION OF THE DRAWINGS

FIG. 1 is an illustration of a vapor deposition apparatus according to a first embodiment of the present invention;

FIG. 2 is an illustration of a vapor deposition apparatus according to a second embodiment of the present invention; and

FIG. 3 is an illustration of a vapor deposition apparatus according to a third embodiment of the present invention.

### DETAILED DESCRIPTION OF THE PREFERRED EMBODIMENTS

A description will be given, with reference to the drawings, of embodiments of the present invention.

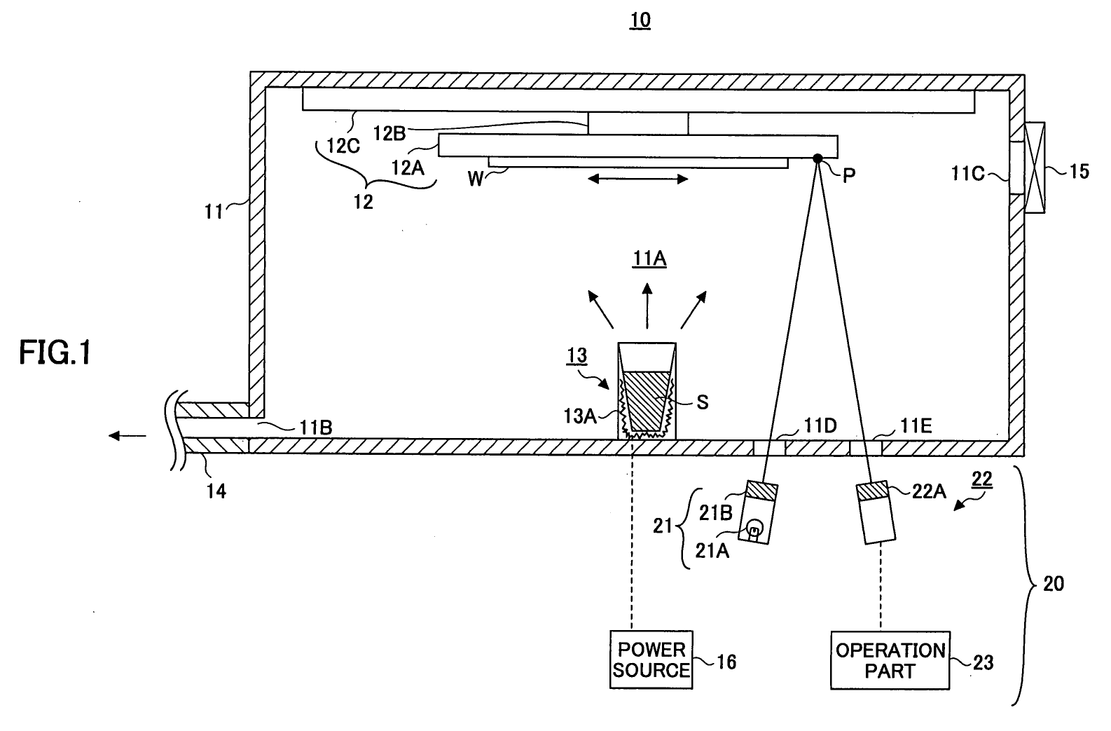

FIG. 1 is an illustration of a vapor deposition apparatus according to a first embodiment of the present invention.

Referring to FIG. 1, the vapor deposition apparatus 10 according to the present embodiment comprises a process container 11 in which a process space 11A is defined, a substrate holding mechanism 12 and a vapor deposition source 13. The substrate holding mechanism 12 and the vapor deposition source 13 are located in the process space 11A. An exhaust port 11B for evacuating gas from the process space 11A is formed in the process container 11. The exhaust port 11B is connected to an exhaust mechanism (not shown) through an exhaust passage 14, and is capable of causing the process space 11A to be in a depressurized state.

A substrate conveyance port 11C provided with a gate valve 15 is formed in the process container 11. By opening the gate valve 15, for example, a substrate W to be processed is carried out of the process space 11A or the substrate W to be processed is carried into the process chamber 11A by, for example, a conveyance apparatus (not shown). The substrate to be processed is held by the substrate holding mechanism 12.

The substrate holding mechanism 12 provided in the process container 11 comprises a guide member 12C, a supporter 12B, a substrate holding part 12A for holding the substrate W to be processed, and a drive device (not shown in the figure). An end of the supporter 12B is supported by the guide member 12C in a rotatable state in a direction generally parallel to the substrate W to be processed. The drive device moves the substrate holding part 12A together with the supporter 12B in a direction generally parallel to the surface of the drive device.

In the vapor deposition source 13, a vapor deposition raw material S of a liquid or a solid is retained. When performing vapor-deposition on the substrate W to be processed, the retained raw material S for vapor deposition (hereinafter, referred to as vapor deposition raw material S) is heated by heating means 13A such as, for example, a heater connected to a power source 16. Thereby, the vapor deposition raw material S is vaporized or sublimated to be vapor. The vaporized or sublimated vapor deposition raw material S is released into the process space 11A, and adheres onto the surface of the substrate W to be processed held by the substrate holding mechanism 12, thereby forming a vapor deposition film. At this time, the vapor of the vapor deposition raw material S adheres onto a surface of each part of the substrate holding mechanism 12 and an inner surface of the process container 11, thereby forming a vapor deposition film.

When performing the vapor deposition, if the vapor deposition is performed while moving the substrate W to be processed, uniformity of the vapor deposition film in the surface of the substrate W to be processed becomes good, which is preferable. Additionally, in this case, by rotating the substrate holding mechanism 12A in addition to move the substrate holding mechanism 12A generally parallel to the substrate, the in-plane uniformity of the vapor deposition film on the substrate W to be processed is further improved.

Conventionally, there is a case in which a problem occurs in controllability of the film thickness of the vapor deposition film formed on the substrate W to be processed. That is, an amount (a vaporizing rate or a sublimating rate) of the vapor deposition raw material S vaporized or sublimated per unit time varies in response to, for example, an amount of the vapor deposition raw material S retained in the vapor deposition source, a slight change of a temperature of the vapor deposition source, and a change in various conditions of the vapor deposition apparatus due to passage of time, and it is difficult to cope with the changes.

Then, in the vapor deposition apparatus 10 according to the present embodiment, film-thickness measuring means (film-thickness measuring device) 20 for measuring the thickness of the vapor deposition film deposited in the process container 11 is provided. The film thickness of the vapor deposition film deposited in the process container 11 can be measured by the film-thickness measuring device 20. Thereby, a vapor deposition film of a desired film thickness can be formed on the substrate W to be processed by the vapor deposition apparatus 10, and the controllability of the film thickness of the vapor deposition, when forming the vapor deposition film, becomes good. For eample, it becomes possible to change or adjust a film forming time so as to be a desired film thickness. Further, in the film deposition apparatus according to the present embodiment, by measuring a change rate of the film thickness per time, it becomes possible to grasp a film forming rate of the vapor deposition film, which is greatly dependent on a change in the vaporizing rate or the sublimating rate. For example, it becomes possible to control the vapor deposition apparatus so as to obtain a desired film thickness so that a desired film forming rate is obtained by changing various conditions relating to the film deposition such as, for example, changing an amount of heating the vapor deposition raw material S by the heating means 13A. Or, it becomes possible to control the vapor deposition apparatus so that a desired film thickness is obtained. Therefore, the effect can be acquired that the controllability of the film thickness of the vapor deposition film formed becomes good.

Moreover, the film thickness measuring device 20 according to the present embodiment measures the thickness of the vapor deposition film by irradiating a light onto the vapor deposition film which is deposited in the process container 11. Thus, for example, when comparing with a film thickness measuring method using a crystal oscillator, there is no need to remove the vapor deposition film deposited on the film thickness measuring device and maintenance of the film thickness measuring apparatus is easy because no vapor deposition film is deposited on the film thickness measuring device. Additionally, since a so-called non-contact measurement is performed in which there is no need to bring any measuring instruments into direct contact with the vapor deposition film, a structure in the process container can be simplified. Additionally, generation of particles in the process container 11 due to exfoliation of the vapor deposition film can be prevented, thereby maintaining inside the process container clean.

There are various methods to measure a film thickness of the vapor deposition film by irradiating a light onto the vapor deposition film. As one example, the film thickness measuring device 20 shown in the FIG. 1 is a device which uses an ellipsometry (polarization analysis). The ellipsometry is a method of acquiring a film thickness or the like of a measuring object film by irradiating a light such as a laser onto the measuring object film and analyzing a change in a polarization state of the light reflected by a surface of the measuring object film. Various measuring instruments including the film measuring device using this method are referred to as ellipsometers.

The film thickness measuring device 20 according to the present embodiment shown in FIG. 1 has light irradiating means (light irradiating part) 21 for irradiating a light such as a laser light onto a vapor deposition film in the process container 11, and a detecting means (detecting part) for detecting a reflected light reflected by the vapor deposition film. The light irradiating part 21 has a light source 21A that emits, for example, a He—Ne laser, and a polarizer 21B. Additionally, a port 11D, which is a light transmitting part to cause the laser light emitted by the light irradiating part 21 to transmit therethrough, and a port 11E, which is a light transmitting part to cause the laser light (reflected light) reflected by the vapor deposition film, are formed at positions corresponding to the light irradiating part 21 and the detecting part 22, respectively, in the process container 11. Additionally, the detecting part 22 is connected with operation means (operation part) 23 for computing the film thickness of the film thickness of the vapor deposition film from the reflected light.

When measuring a film thickness of the vapor deposition film formed in the process container 11 using the film thickness measuring device 20, first, the laser light is irradiated by the light irradiating part 21 onto the vapor deposition film in the process container 11. Then, the reflected light reflected by the vapor deposition film is detected by the detecting part 22. The operation part 23 analyzes a change in a polarization state of the laser light, which is the reflected light, and computes the film thickness of the vapor deposition film based on the analysis.

The position of the measurement point P on the vapor deposition film at which the laser light from the light irradiating part 21 is irradiated can be set variously.

For example, if the measuring point P is set to the substrate holding part 12A that holds the substrate W to be processed, there is less difference from the film thickness of the vapor deposition film deposited on the substrate W to be processed, which is preferable. It is possible to irradiate the laser light form the irradiating part 21 directly onto the substrate W to be processed, but there may be a case in which an influence is given to the vapor deposition film deposited on the substrate W to be processed depending on a power of the laser light. Thus, it is preferable to irradiate the laser light by the light irradiating part 21 by setting the measurement point to the substrate holding part 12A at a position avoiding the substrate W to be processed and in the vicinity of the substrate W to be processed.

However, the measurement point P can be set on the substrate W to be processed. Particularly, if it is set on a device formed on the substrate W to be processed, a thickness of a film actually formed on the device can be measured accurately, which is preferable. In this case, it is preferable to reduce the power of the laser light so as to not giving an influence to the device.

Moreover, for example, the measurement point P may be set near an end part in which no device is formed on the substrate W to be processed, or may be set on the substrate W to be processed. It is also possible to set the measurement point P on a mask (not shown in the figure) formed on the substrate W to be processed.

Moreover, the film thickness measuring device for measuring a film thickness of a vapor deposition film by irradiating a light is not limited to the above-mentioned structure, and various constructions and types can be used as mentioned below.

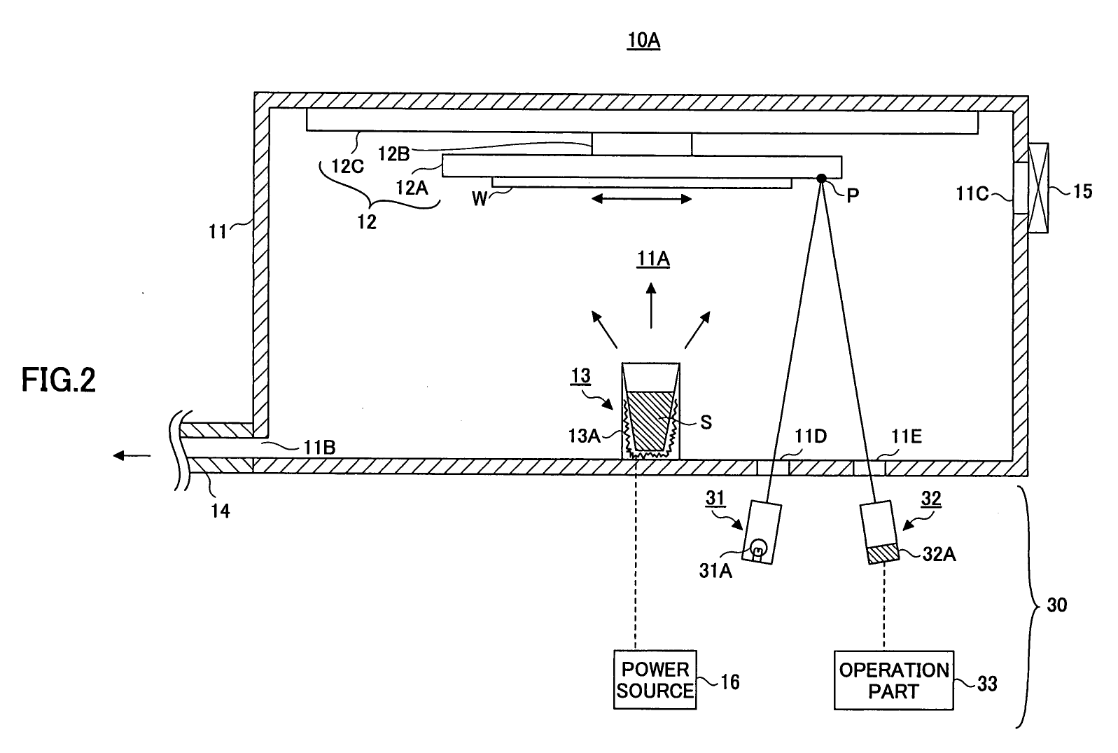

A description will now be given, with reference to FIG. 2, of a vapor deposition apparatus 10A according to a second embodiment of the present invention. In FIG. 2, parts that are the same as the parts shown in FIG. 1 are given the same reference numerals, and descriptions thereof will be omitted.

The vapor deposition apparatus 10A shown in FIG. 2 uses film thickness measuring means (film thickness measuring device) 30 for measuring a film thickness of a vapor deposition film formed in the process container 11. The film thickness measuring device 30 according to the present embodiment comprises light irradiating means (light irradiating part) 31 for irradiating a light such as a laser light onto a vapor deposition film in the process chamber 11, and luminescence measuring means (luminescence measuring part) 32 for measuring a luminescence intensity of a luminescence of the vapor deposition film according to the irradiation of the light.

When light is irradiated onto the vapor deposition film deposited in the process container 11, if the light has energy higher than a forbidden band of the material forming the vapor deposition film, electron-hole pairs are generated in the vapor deposition film. Then, a luminescence is generated when the electron-hole pairs are recombined. Such a phenomenon may be referred to as photoluminescence. The film thickness measuring device 30 according the present embodiment calculates a film thickness of the vapor deposition film based on the luminescence intensity of the luminescence of the vapor deposition film according to such an irradiation of a light.

The light radiating part 31 has a light source 31A, which emits a laser light such as an Ar-ion laser or a He—Cd laser. The detecting part 22 has a measuring part 32A, which measures a luminescence intensity of the luminescence of the vapor deposition film. A port 11D for causing the laser light emitted by the light irradiating part 31 to transmit therethrough and a port 11E for causing the light emitted from the vapor deposition film according to the irradiation of the laser light to transmit therethrough are formed at positions corresponding to the light irradiating part 31 and the luminescence measuring part 32, respectively, in the process container 11. Additionally, the detecting part 32 is connected with operation means (operation part) 33 for computing the film thickness of the film thickness of the vapor deposition film from the luminescence.

When measuring a film thickness of the vapor deposition film formed in the process container 11 using the film thickness measuring device 30, first, the light irradiating part 31 irradiates a light such as, for example, a laser light onto the vapor deposition film in the process container 11. The luminescence measuring part 32 measures a luminescence intensity of the luminescence of the vapor deposition film according to the irradiation of the light. The operation part 33 computes the film thickness of the vapor deposition film based on the measured luminescence intensity.

The position of the measurement point P on the vapor deposition film at which the laser light from the light irradiating part 31 is irradiated can be set to various positions the same as the above-mentioned first embodiment.

The film thickness measurement according to the present embodiment is particularly suitable for a case in which the vapor deposition film deposited in the process container is a material, which is excited by irradiation of a light and easily generates a luminescence. For example, in a case where an organic EL element is formed, a vapor deposition film which tends to generate such a phenomenon is formed. Accordingly, the film thickness measurement according to the present embodiment is particularly effective when forming an organic EL element.

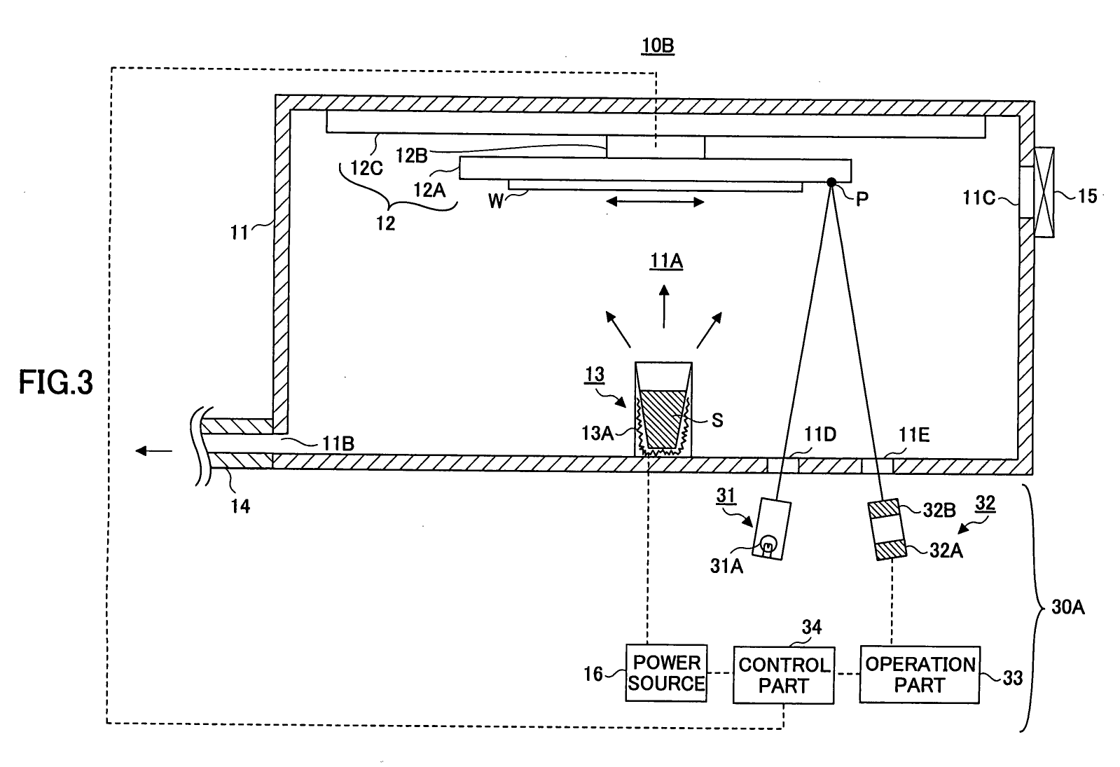

Next, a description will be given, with reference to FIG. 3, of a vapor deposition apparatus 10B according to a third embodiment of the present invention. In FIG. 3, parts that are the same as the part shown in FIG. 1 and FIG. 2 are given the same reference numerals, and descriptions thereof will be omitted.

The vapor deposition apparatus 10B shown in FIG. 3 has a structure in which control means (control part) 34 is provided to the vapor deposition apparatus 10A according to the second embodiment shown in FIG. 2. The control part 34 is connected to the operation part 33.

The control part 34 controls the vapor deposition apparatus 10B in accordance with a film thickness of a vapor deposition film deposited in the process container 11 or a deposition rate of the vapor deposition film or calculation data of changes in the deposition rate of the vapor deposition. For example, the control part 34 controls an amount of heating of the heater 13A connected to the power source 16 by controlling the output of the power source 16. Thereby, an amount of the vapor deposition raw material S to vaporize or sublimate is controlled, and a film deposition rate of the vapor deposition film can be adjusted. Thus, the film deposition rate can be stabilized and an effect can be obtained that the controllability of a film thickness of a vapor deposition film being formed becomes good.

Moreover, the control part 34 may be constituted so as to control the substrate holding mechanism 12. In this case, a film deposition rate of a vapor deposition film is controlled by controlling a moving speed or an amount of movement of the substrate holding part 12. Thereby, the film deposition rate can be stabilized and the controllability of a film thickness of a vapor deposition film being formed can be good.

Thus, the vapor deposition apparatus of which controllability of a film thickness is good can be realized by measuring a film thickness measured by the film thickness measuring device 30A or a change rate of a film thickness per time and setting the apparatus structure to feed back those values to the vapor deposition apparatus by the control means.

Moreover, the film thickness or the film deposition rate measured by the film thickness measuring device 30A is not limited to use for the control of a setting temperature of the vapor deposition source 13 as mentioned above. For example, it can be fed back to a control of a setting temperature of the substrate W to be processed, a pressure in the process container 11 or a moving speed of the substrate holding mechanism. Thereby, the controllability of a film thickness can be further good, and the vapor deposition apparatus having good reproducibility of a film thickness can be realized.

Moreover, in the film thickness measuring device 30A according to the present embodiment, the detecting part 32 has spectrometry means (spectrometry part) 32B so that spectrometry of the luminescence of the vapor deposition film can be performed. The luminescence of the vapor deposition film includes lights of various wavelengths. For example, by performing spectrometry, a film thickness of a vapor deposition film can be calculated using an intensity of a predetermined wavelength on which the film thickness of the vapor deposition film strongly depends, by analyzing spectra of the luminescence.

An organic vapor deposition film was formed on substrates W to be processed using Alq3 as the vapor deposition raw material S retained by the vapor deposition source 13 by using the above-mentioned vapor deposition apparatus, and it was confirmed that a variation of the thickness of the films formed on the plurality of substrates to be processed is ±2%.

Moreover, although the vapor deposition apparatus according to each of the above-mentioned embodiments has a single vapor deposition source, the present invention is not limited to this and a plurality of vapor deposition sources may be provided. Additionally, a vapor deposition film having various elements can be formed using various raw materials by the vapor deposition apparatus according to the present invention. Additionally, the structure of the vapor deposition is not limited to the above-mentioned apparatus structure, and various structures may be used. For example, the film thickness measuring device can be arranged at an arbitrary location, and the measurement point can be set to various positions.

The present invention is not limited to the specifically disclosed embodiments, and variations and modifications may be made without departing from the scope of the present invention.

The present application is based on Japanese priority application No. 2004-371407 filed Dec. 22, 2004, the entire contents of which are hereby incorporated herein by reference.

What is claimed is:

1. A vapor deposition apparatus comprising:
a process container in which a substrate to be processed is accommodated;
a vapor deposition source that retains a vapor deposition material to be deposited on the substrate to be processed; and
a measuring device that measures a film thickness of a vapor deposition film produced in said process container,
wherein said measuring device measures the film thickness by irradiating a light onto said vapor deposition film.

2. The vapor deposition apparatus as claimed in claim 1, wherein the light is a laser light.

3. The vapor deposition apparatus as claimed in claim 1, wherein the light is irradiated onto the vapor deposition film produced in a vicinity of said substrate to be processed in said process container.

4. The vapor deposition apparatus as claimed in claim 1, wherein said measuring device is an ellipsometer.

5. The vapor deposition apparatus as claimed in claim 1, wherein said measuring device comprises:
a light irradiating part that irradiates the light onto the vapor deposition film; and
a light measuring part that measures a luminescence intensity of luminescence of the vapor deposition film according to irradiation of the light.

6. The vapor deposition apparatus as claimed in claim 5, comprising a spectrometry part that performs spectrometry on the luminescence of the vapor deposition film.

7. The vapor deposition apparatus as claimed in claim 5, comprising a control part that controls said vapor deposition source in accordance with the luminescence intensity.

8. The vapor deposition apparatus as claimed in claim 7, wherein said control part controls a heater provided in said vapor deposition source.

9. The vapor deposition apparatus as claimed in claim 1, wherein said measuring device is provided outside said process container.

10. The vapor deposition apparatus as claimed in claim 9, wherein said process container has a light-transmitting part that causes the light to transmit therethrough.
